(19) United States
(12) Patent Application Publication
(10) Pub. No.: US 2025/0318060 A1
(43) Pub. Date: Oct. 9, 2025

(54) ELECTRONIC DEVICE FOR CONTROLLING DRIVING MODULE ON BASIS OF DETECTION OF FALL, AND CONTROL METHOD THEREFOR

(71) Applicant: Samsung Electronics Co., Ltd., Suwon-si (KR)

(72) Inventors: Junwoo CHOI, Suwon-si (KR); Oheon KWON, Suwon-si (KR); Hyoungtak CHO, Suwon-si (KR); Hyunggwang KANG, Suwon-si (KR); Jihea PARK, Suwon-si (KR)

(21) Appl. No.: 19/245,969

(22) Filed: Jun. 23, 2025

Related U.S. Application Data
(63) Continuation of application No. PCT/KR2023/021458, filed on Dec. 22, 2023.

(30) Foreign Application Priority Data
Dec. 23, 2022 (KR) 10-2022-0182675
Dec. 27, 2022 (KR) 10-2022-0186108

(51) Int. Cl. H05K 5/02

(52) U.S. Cl. CPC H05K 5/0217

(57) ABSTRACT

An electronic device for controlling a driving module on the basis of detection of a fall, and/or a control method therefor. The control method for the electronic device may include: identifying whether the electronic device is falling based on sensing data transmitted from at least one sensor included in a second housing of the electronic device; outputting an interrupt signal through a first port of a component of the electronic device based on identifying that the electronic device is falling; and outputting, to at least one driving module of the electronic device, a control command for controlling the at least one driving module in order to insert the second housing extracted from a first housing into the first housing of the electronic device, based on receiving the output interrupt signal through a second port of a processor directly connected to the first port.

### CROSS-REFERENCE TO RELATED APPLICATIONS

This application is a continuation application of International Application No. PCT/KR2023/021458, filed on Dec. 22, 2023, in the Korean Intellectual Property Receiving Office, and claiming priority to Korean Patent Application No. 10-2022-0182675 filed Dec. 23, 2022, and Korean Patent Application No. 10-2022-0186108, filed on Dec. 27, 2022, the disclosures of which are all hereby incorporated by reference herein in their entireties.

### TECHNICAL FIELD

Certain example embodiments may relate to an electronic device for controlling a driving module based on detecting a fall, and/or a method for controlling the same.

### BACKGROUND

More and more services and additional functions are being provided through electronic devices, e.g., smartphones, or other portable electronic devices. To meet the needs of various users and raise use efficiency of electronic devices, communication service carriers or device manufacturers are jumping into competitions to develop electronic devices with differentiated and diversified functionalities. Accordingly, various functions that are provided through electronic devices are evolving more and more.

The above-described information may be provided as related art for the purpose of helping understanding of the disclosure. No claim or determination is made as to whether any of the foregoing is applicable as background art in relation to the disclosure.

### SUMMARY

When a fall of an electronic device (e.g., a slidable electronic device configured so that at least a portion of a flexible display is inserted into a housing or drawn out from the housing) is detected, a driving module (e.g., a motor) of the electronic device may be controlled to switch the electronic device from an extended state to a closed state. A fall interrupt signal (e.g., an interrupt for outputting a control command for controlling a driving module based on identifying that the electronic device is falling) and/or a control command for controlling (e.g., driving a motor in a direction in which the flexible display is inserted from the drawn-out state) may be transmitted to a corresponding module (e.g., a framework or a motor driver included in the kernel) based on a conventional software (SW) stack. For example, the fall interrupt signal may be transmitted to the framework via the kernel and the hardware abstraction layer (HAL), and the control command may be transmitted to the kernel (e.g., the motor driver) via the framework and/or the file system layer. The control command for driving the driving module may be transmitted to the driving module via such transmission process. However, the conventional signal transmission process takes a long time until the driving module is controlled after the electronic device (e.g., the processor) detects a fall in the emergency such as a fall of the electronic device, and may not be applied to special situations such as a fall.

An electronic device according to an example embodiment may comprise a first housing, a second housing disposed to be movable with respect to the first housing and overlapping at least a portion of the first housing, at least one processor, a driving module, and at least one sensor disposed in the second housing, and a flexible display at least partially mounted on (directly or indirectly) a surface of the second housing and at least partially exposed to an outside of the electronic device. A portion of the flexible display may be inserted into or drawn out of the first housing according to driving of the driving module. The at least one processor, comprising processing circuitry, may be configured to, based on sensing data transmitted from the at least one sensor, identify whether the electronic device is falling, based on identifying that the electronic device is falling, output an interrupt signal through a first port of a component of the electronic device, and output, to the at least one driving module, a control command for controlling the at least one driving module to insert the second housing drawn out from the first housing into the first housing based on receiving the output interrupt signal through a second port of the processor directly connected to the first port.

A method for controlling an electronic device according to an example embodiment may comprise, based on sensing data transmitted from at least one sensor included in a second housing of the electronic device, identifying whether the electronic device is falling, based on identifying that the electronic device is falling, outputting an interrupt signal through a first port of a component of the electronic device, and outputting, to the at least one driving module, a control command for controlling at least one driving module of the electronic device to insert the second housing drawn out from a first housing of the electronic device into the first housing based on receiving the output interrupt signal through a second port of the processor directly connected to the first port.

One or more non-transitory computer-readable storage media according to an example embodiment may store instructions that, when executed by at least one processor of an electronic device individually or collectively cause the electronic device to perform operations. The operations comprising, based on sensing data transmitted from at least one sensor included in a second housing of the electronic device, identifying whether an electronic device is falling, based on identifying that the electronic device is falling, outputting an interrupt signal through a first port of a component of the electronic device; and based on receiving the output interrupt signal through a second port of a processor connected to the first port, outputting, to the at least one driving module, a control command for controlling at least one driving module of the electronic device to insert the second housing drawn out from a first housing of the electronic device into the first housing.

There may be provided an electronic device capable of significantly reducing latency due to the conventional fall interrupt signal transmission/reception process by transmitting/receiving a fall interrupt through a port (e.g., the second GPIO port of the processor) directly connected to a port (e.g., the first GPIO port of the processor) where the fall interrupt signal is output.

There may be provided an electronic device capable of significantly reducing latency due to the conventional fall interrupt signal transmission/reception process by transmitting/receiving a fall interrupt through a module (e.g., the motor driver of the kernel) directly connected to a module (e.g., the sensor hub module) configured to output a fall interrupt signal.

### BRIEF DESCRIPTION OF THE DRAWINGS

FIG. 1 is a block diagram illustrating an electronic device in a network environment according to various example embodiments;

FIG. 2 is a view illustrating a state in which a second display area of a display is received in a housing according to various example embodiments;

FIG. 3 is a view illustrating a state in which a second display area of a display is exposed to the outside of a housing according to various example embodiments;

FIG. 4 is an exploded perspective view illustrating an electronic device according to various example embodiments;

FIG. 5A is a cross-sectional view taken along line A-A′ of FIG. 2 according to various example embodiments;

FIG. 5B is a cross-sectional view taken along line B-B′ of FIG. 3 according to various example embodiments;

FIG. 6 is an exemplary view illustrating a function or operation for reducing latency of signal transmission by transmitting/receiving a fall interrupt signal through directly connected ports according to an example embodiment;

FIGS. 7 and 8 are exemplary views illustrating a function or operation for transmitting/receiving a fall interrupt signal through ports (e.g., a first port and a second port) of a processor from a hardware perspective according to an example embodiment; and

FIGS. 9A and 9B are exemplary views illustrating a function or operation for transmitting/receiving a fall interrupt signal through ports (e.g., a first port and a second port) of a processor from a software perspective according to an example embodiment.

### DETAILED DESCRIPTION

Hereinafter, example embodiments are described in detail with reference to the drawings so that those skilled in the art to which the disclosure pertains may easily practice the disclosure. However, the disclosure may be implemented in other various forms and is not limited to the embodiments set forth herein. The same or similar reference denotations may be used to refer to the same or similar elements throughout the specification and the drawings. Further, for clarity and brevity, no description is made of well-known functions and configurations in the drawings and relevant descriptions.

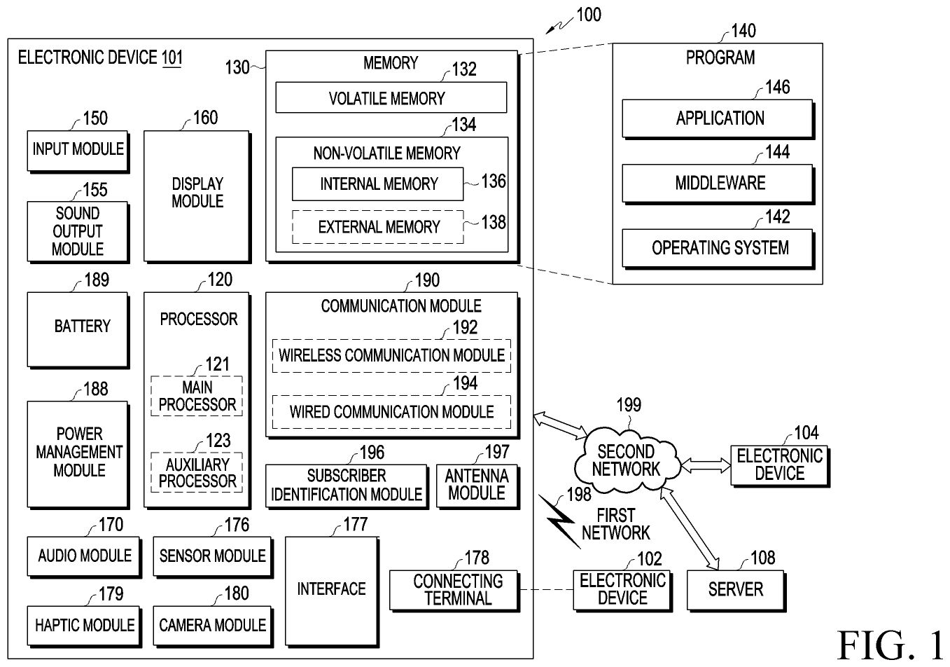

FIG. 1 is a block diagram illustrating an electronic device 101 in a network environment 100 according to various embodiments.

Referring to FIG. 1, the electronic device 101 in the network environment 100 may communicate with at least one of an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display 160 may include, for example, a display, a hologram device, or a projector and control circuitry to control a corresponding one of the display, hologram device, and projector. According to an embodiment, the display 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an accelerometer, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module 197 may include one antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or health-care) based on 5G communication technology or IoT-related technology.

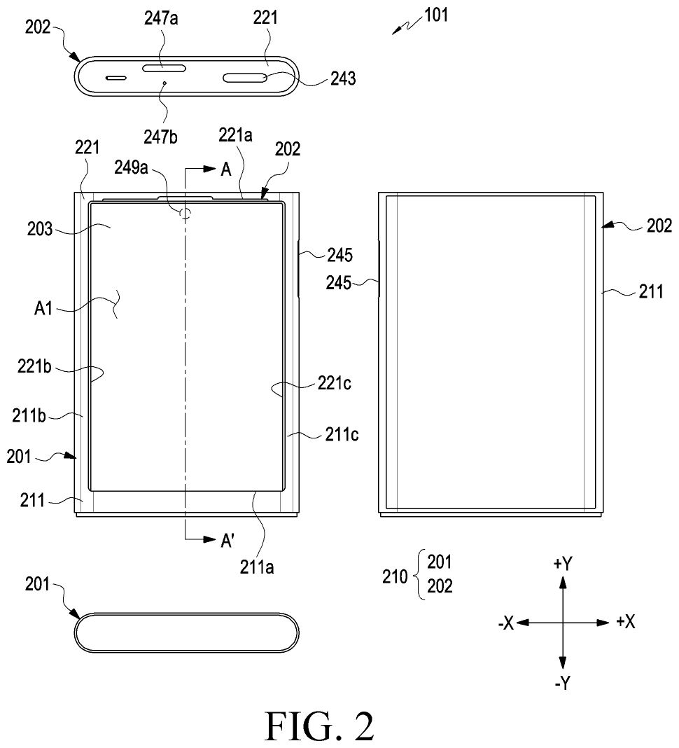

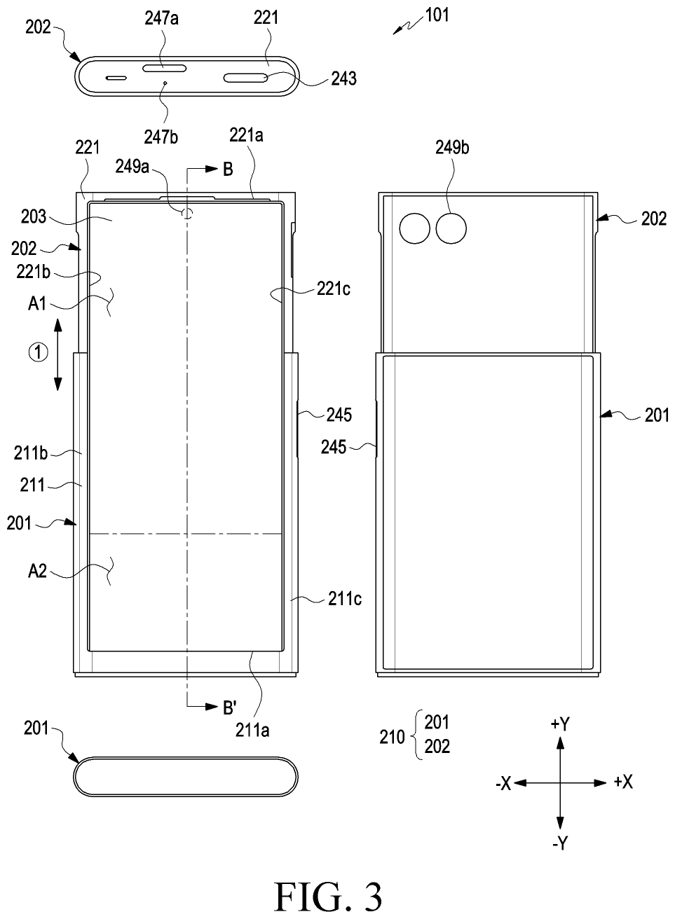

FIG. 2 is a view illustrating a state in which a second display area of a display is received in a housing according to various example embodiments. FIG. 3 is a view illustrating a state in which a second display area of a display is exposed to the outside of a housing according to various example embodiments.

FIGS. 2 and 3 illustrate a structure in which the display 203 (e.g., flexible display or rollable display) is extended in the length direction (e.g., +Y direction) when the electronic device 101 is viewed from the front. However, the extending direction of the display 203 is not limited to one direction (e.g., +Y direction). For example, the extending direction of the display 203 may be changed in design to be extendable in the upper direction (+Y direction), right direction (e.g., +X direction), left direction (e.g., −X direction), and/or lower direction (e.g., −Y direction).

The state shown in FIG. 2 may be referred to as a closed state of the electronic device 101 or housing 210 and a slide-in state of the display 203.

The state shown in FIG. 3 may be referred to as an opened state of the electronic device 101 or housing 210 and a slide-out state of the display 203.

Referring to FIGS. 2 and 3, the electronic device 101 may include a housing 210. The housing 210 may include a first housing 201 and a second housing 202 disposed to be movable relative to the first housing 201. According to an embodiment, the electronic device 101 may be interpreted as having a structure in which the first housing 201 is disposed to be slidable with respect to the second housing 202. According to an embodiment, the second housing 202 may be disposed to perform reciprocating motion by a predetermined distance in the shown direction with respect to the first housing 201, for example, a direction indicated by the arrow n.

According to various embodiments, the second housing 202 may be referred to as a slide portion or a slide housing, and may be movable relative to the first housing 201. According to an embodiment, the second housing 202 may receive various electrical/electronic components, such as a circuit board or a battery.

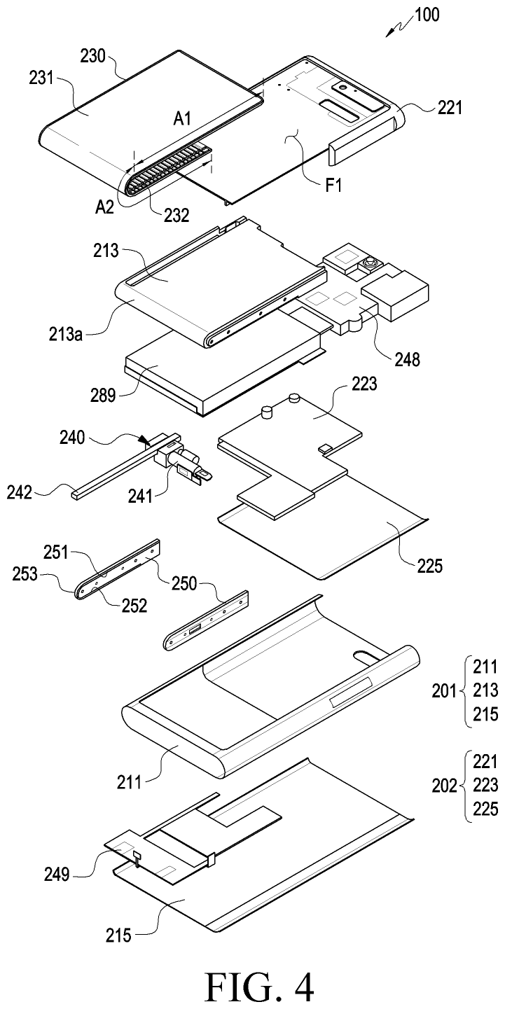

According to an embodiment, the first housing 201 may accommodate a sub circuit board (e.g., the second circuit board 249 of FIG. 4) electrically connected to a motor, a speaker, a SIM socket, and/or the main circuit board. The second housing 202 may accommodate a main circuit board (e.g., the first circuit board 248 of FIG. 4) on which electrical components such as an application processor (AP) and a communication processor (CP) are mounted.

According to various embodiments, the first housing 201 may include a first cover member 211 (e.g., a main case). The first cover member 211 may include a 1-1th sidewall 211a, a 1-2th sidewall 211b extending from the 1-1th sidewall 211a, and a 1-3th sidewall 211c extending from the 1-1th sidewall 211a and substantially parallel to the 1-2th sidewall 211b. According to an embodiment, the 1-2th sidewall 211b and the 1-3th sidewall 211c may be formed substantially perpendicular to the 1-1th sidewall 211a.

According to various embodiments, the 1-1th sidewall 211a, 1-2th sidewall 211b, and 1-3th sidewall 211c of the first cover member 211 may be formed to have a side opening (e.g., in the front surface) to receive at least a portion of the second housing 202. For example, at least a portion of the second housing 202 may be surrounded by the first housing 201 and be slid in the direction parallel to the first surface (e.g., the first surface F1 of FIG. 4), e.g., arrow \textcircled{1} direction, while being guided by the first housing 201. According to an embodiment, the 1-1th sidewall 211a, the 1-2th sidewall 211b, and/or the 1-3th sidewall 211c of the first cover member 211 may be integrally formed. According to an embodiment, the 1-1th sidewall 211a, the 1-2th sidewall 211b, and/or the 1-3th sidewall 211c of the first cover member 211 may be formed as separate structures and be combined or assembled.

According to various embodiments, the first cover member 211 may be formed to surround at least a portion of the display 203. For example, at least a portion of the display 203 may be formed to be surrounded by the 1-1th sidewall 211a, the 1-2th sidewall 211b, and/or the 1-3th sidewall 211c of the first cover member 211.

According to various embodiments, the second housing 202 may include a second cover member 221 (e.g., a slide plate). The second cover member 221 may have a plate shape and include a first surface (e.g., the first surface F1 of FIG. 4) supporting internal components. For example, the second cover member 221 may support at least a portion of the display 203 (e.g., the first display area A1). According to an embodiment, the second cover member 221 may be referred to as a front cover.

According to an embodiment, the second cover member 221 may include a 2-1th sidewall 221a, a 2-2th sidewall 221b extending from the 2-1th sidewall 221a, and a 2-3th sidewall 221c extending from the 2-1th sidewall 221a and substantially parallel to the 2-2th sidewall 221b. According to an embodiment, the 2-2th sidewall 221b and the 2-3th sidewall 221c may be formed substantially perpendicular to the 2-1th sidewall 221a.

According to various embodiments, as the second housing 202 moves in a first direction (e.g., direction n) parallel to the 1-2th sidewall 211b or the 1-3th sidewall 211c, it may form an opened state and a closed state of the housing 210. In the closed state, the second housing 202 may be positioned at a first distance from the 1-1th sidewall 211a and, in the opened state, the second housing 202 may be moved to be positioned at a second distance larger than the first distance from the 1-1th sidewall 211a. In some embodiments, in the closed state, the first housing 201 may surround a portion of the 2-1th side wall 221a.

According to various embodiments, the electronic device 101 may include a display 203, a key input device 245, a connector hole 243, audio modules 247a and 247b, or camera modules 249a and 249b. According to an embodiment, the electronic device 101 may further include an indicator (e.g., a light emitting diode (LED) device) or various sensor modules.

According to various embodiments, the display 203 may include a first display area A1 and a second display area A2 configured to be exposed to the outside of the electronic device 101 based on the slide of the second housing 202. According to an embodiment, the first display area A1 may be disposed on the second housing 202. For example, the first display area A1 may be disposed on the second cover member 221 of the second housing 202. According to an embodiment, the second display area A2 may extend from the first display area A1, and as the second housing 202 slides relative to the first housing 201, the second display area A2 may be received in the first housing 201 (e.g., the slide-in state) or be visually exposed to the outside of the electronic device 101 (e.g., the slide-out state).

According to various embodiments, the second display area A2 may be moved while being substantially guided by one area (e.g., the curved surface 213a of FIG. 4) of the first housing 201 and be received in the space positioned in the first housing 201 or exposed to the outside of the electronic device 101. According to an embodiment, the second display area A2 may move based on a slide of the second housing 202 in the first direction (e.g., the direction indicated by the arrow n). For example, while the second housing 202 slides, a portion of the second display area A2 may be deformed into a curved shape in a position corresponding to the curved surface 213a of the first housing 201.

According to various embodiments, when viewed from above the second cover member 221 (e.g., front cover), if the electronic device 210 changes from the closed state to opened state (e.g., if the second housing 202 slides to extend from the first housing 201), the second display area A2 may be gradually exposed to the outside of the first housing 201 and, together with the first display area A1, form a substantially flat surface. According to an embodiment, the display 203 may be coupled with or disposed adjacent to a touch detection circuit, a pressure sensor capable of measuring the strength (pressure) of touches, and/or a digitizer for detecting a magnetic field-type stylus pen. According to an embodiment, irrespective of the closed state or opened state of the housing 210, the portion of the second display area A2 may be positioned on a portion (e.g., the curved surface 213a of FIG. 4) of the first housing, and a portion of the second display area A2 may remain in the curved shape in the position corresponding to the curved surface 213a.

According to various embodiments, the key input device 245 may be positioned in one area of the first housing 201. Depending on the appearance and the state of use, the electronic device 101 may be designed to omit the illustrated key input device 245 or to include additional key input device(s). According to an embodiment, the electronic device 101 may include a key input device (not shown), e.g., a home key button or a touchpad disposed around the home key button. According to an embodiment, at least a portion of the key input device 245 may be disposed on the 1-1th sidewall 211a, the 1-2th sidewall 211b, or the 1-3th sidewall 211c of the first housing 201.

According to various embodiments, the connector hole 243 may be omitted or may receive a connector (e.g., a universal serial bus (USB) connector) for transmitting and receiving power and/or data with an external electronic device. According to an embodiment (not shown), the electronic device 101 may include a plurality of connector holes 243, and some of the plurality of connector holes 243 may function as connector holes for transmitting/receiving audio signals with an external electronic device. In the illustrated embodiment, the connector hole 243 is disposed in the second housing 202, but is not limited thereto. For example, the connector hole 243 or a connector hole not shown may be disposed in the first housing 201.

According to various embodiments, the audio modules 247a and 247b may include at least one speaker hole 247a or at least one microphone hole 247b. One of the speaker holes 247a may be provided as a receiver hole for voice calls, and the other may be provided as an external speaker hole. The electronic device 101 may include a microphone for obtaining sound. The microphone may obtain external sound of the electronic device 101 through the microphone hole 247b. According to an embodiment, the electronic device 101 may include a plurality of microphones to detect the direction of sound. According to an embodiment, the electronic device 101 may include an audio module in which the speaker hole 247a and the microphone hole 247b are implemented as one hole or may include a speaker without the speaker hole 247a (e.g., a piezo speaker).

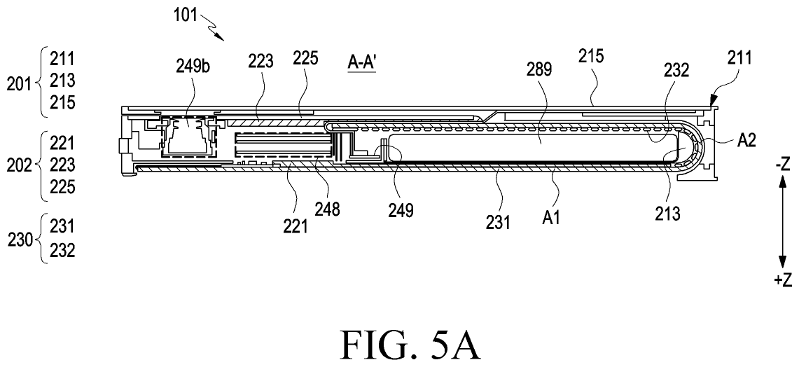

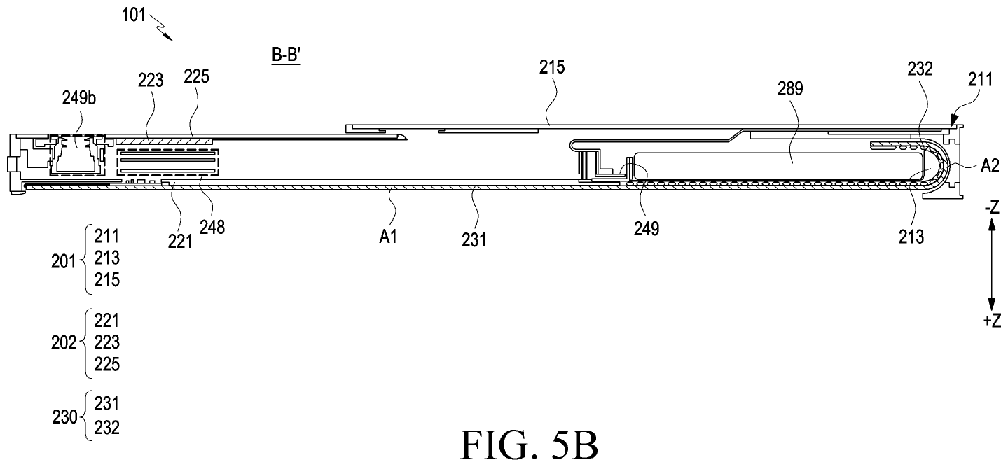

According to various embodiments, the camera modules 249a and 249b may include a first camera module 249a (e.g., a front camera) and a second camera module 249b (e.g., a rear camera) (e.g., the second camera module 249b of FIGS. 5A and 5B). According to an embodiment, the electronic device 101 may include at least one of a wide-angle camera, a telephoto camera, or a close-up camera. According to an embodiment, the electronic device 200 may measure the distance to the subject by including an infrared projector and/or an infrared receiver. The camera modules 249a and 249b may include one or more lenses, an image sensor, and/or an image signal processor. The first camera module 249a may be disposed to face in the same direction as the display 203. For example, the first camera module 249a may be disposed in an area around the first display area A1 or overlapping the display 203. When disposed in the area overlapping the display 203, the first camera module 249a may capture the subject through the display 203. According to an embodiment, the first camera module 249a may include an under display camera (UDC) that has a screen display area (e.g., the first display area A1) that may not be visually exposed but hidden. According to an embodiment, the second camera module 249b may capture the subject in a direction opposite to the first display area A1. According to an embodiment, the first camera module 249a and/or the second camera module 249b may be disposed on the second housing 202.

According to various embodiments, an indicator (not shown) of the electronic device 101 may be disposed on the first housing 201 or the second housing 202, and the indicator may include a light emitting diode to provide state information about the electronic device 101 as a visual signal. The sensor module (e.g., the sensor module 176 of FIG. 1) of the electronic device 101 may produce an electrical signal or data value corresponding to the internal operation state or external environment state of the electronic device. The sensor module may include, for example, a proximity sensor, a fingerprint sensor, or a biometric sensor (e.g., an iris/face recognition sensor or a heartrate monitor (HRM) sensor). According to another embodiment, the sensor module may further include, e.g., at least one of a gesture sensor, a gyro sensor, an atmospheric pressure sensor, a magnetic sensor, an acceleration sensor, a grip sensor, a color sensor, an infrared (IR) sensor, a temperature sensor, a humidity sensor, or an illuminance sensor.

FIG. 4 is an exploded perspective view illustrating an electronic device according to various example embodiments.

FIG. 5A is a cross-sectional view taken along line A-A′ of FIG. 2 according to various example embodiments.

FIG. 5B is a cross-sectional view taken along line B-B′ of FIG. 3 according to various example embodiments.

Referring to FIGS. 4, 5A, and/or 5B, an electronic device 101 may include a first housing 201, a second housing 202, a display assembly 230, and a driving structure 240. The configuration of the first housing 201, the second housing 202, and the display assembly 230 of FIGS. 4, 5A, and/or 5B may be identical in whole or part to the configuration of the first housing 201, the second housing 202, and the display 203 of FIGS. 2 and/or 3.

According to various embodiments, the first housing 201 may include a first cover member 211 (e.g., the first cover member 211 of FIGS. 2 and 3), a frame 213, and a first rear plate 215.

According to various embodiments, the first cover member 211 may receive at least a portion of the frame 213 and receive a component (e.g., battery 289) positioned in the frame 213. According to an embodiment, the first cover member 211 may be formed to surround at least a portion of the second housing 202. According to an embodiment, the second circuit board 249 receiving the electronic component (e.g., the processor 120 and/or the memory 130 of FIG. 1) may be disposed on the first cover member 211.

According to various embodiments, the frame 213 may be connected to the first cover member 211. For example, the frame 213 may be connected to the first cover member 211. The second housing 202 is movable relative to the first cover member 211 and/or the frame 213. According to an embodiment, the frame 213 may receive a battery 289 (e.g., the battery 189 of FIG. 1). According to an embodiment, the frame 213 may include a curved portion 213a facing the display assembly 230.

According to various embodiments, the first rear plate 215 may substantially form at least a portion of the exterior of the first housing 201 or the electronic device 101. For example, the first rear plate 215 may be coupled to the outer surface of the first cover member 211. According to an embodiment, the first rear plate 215 may provide a decorative effect on the exterior of the electronic device 101. The first rear plate 215 may be formed of at least one of metal, glass, synthetic resin, or ceramic.

According to various embodiments, the second housing 202 may include a second cover member 221 (e.g., the second cover member 221 of FIGS. 2 and 3), a rear cover 223, and a second rear plate 225.

According to an embodiment, the second cover member 221 may be connected to the first housing 201 through the guide rail 250 and, while being guided by the guide rail 250, reciprocate linearly in one direction (e.g., the direction of arrow n in FIG. 3).

According to various embodiments, the second cover member 221 may support at least a portion of the display 203. For example, the second cover member 221 may include a first surface F1. The first display area A1 of the display 203 may be substantially positioned on the first surface F1 to maintain a flat panel shape. According to an embodiment, the second cover member 221 may be formed of a metal material and/or a non-metal (e.g., polymer) material. According to an embodiment, the first circuit board 248 receiving the electronic component (e.g., the processor 120 and/or the memory 130 of FIG. 1) may be disposed on the second cover member 221.

According to various embodiments, the rear cover 223 may protect a component (e.g., the first circuit board 248) positioned on the second cover member 221. For example, the rear cover 223 may be connected to the second cover member 221 and may be formed to surround at least a portion of the first circuit board 248. According to an embodiment, the rear cover 223 may include an antenna pattern for communicating with an external electronic device. For example, the rear cover 223 may include a laser direct structuring (LDS) antenna.

According to various embodiments, the second rear plate 225 may substantially form at least a portion of the exterior of the second housing 202 or the electronic device 101. For example, the second rear plate 225 may be coupled to the outer surface of the second cover member 221. According to an embodiment, the second rear plate 225 may provide a decorative effect on the exterior of the electronic device 101. The second rear plate 215 may be formed of at least one of metal, glass, synthetic resin, or ceramic.

According to various embodiments, the display assembly 230 may include a display 231 (e.g., the display 203 of FIGS. 2 and/or 3) and a multi-bar structure 232 supporting the display 203. According to an embodiment, the display 231 may be referred to as a flexible display, a foldable display, and/or a rollable display.

According to various embodiments, the multi-bar structure 232 may be connected to or attached to at least a portion (e.g., the second display area A2) of the display 231. According to an embodiment, as the second housing 202 slides, the multi-bar structure 232 may move with respect to the first housing 201. In the closed state of the electronic device 101 (e.g., the state of FIG. 2), the multi-bar structure 232 may be mostly received in the first housing 201 and may be positioned between the first cover member 211 and the second cover member 221. According to an embodiment, at least a portion of the multi-bar structure 232 may move corresponding to the curved surface 213a positioned at the edge of the frame 213. According to an embodiment, the multi-bar structure 232 may be referred to as a display supporting member or supporting structure and may be in the form of one elastic plate.

According to various embodiments, the driving structure 240 may move the second housing 202 relative to the first housing 201. For example, the drive structure 240 may include a motor 241 configured to generate a driving force for sliding the housing 201 and 202. The driving structure 240 may include a gear (e.g., a pinion) connected to the motor 241 and a rack 242 configured to mesh with the gear.

According to various embodiments, the housing in which the rack 242 is positioned and the housing in which the motor 241 is positioned may be different. According to an embodiment, the motor 241 may be connected to the second housing 202. The rack 242 may be connected to the first housing 201. According to another embodiment, the motor 241 may be connected to the first housing 201. The rack 242 may be connected to the second housing 202.

According to various embodiments, the first housing 201 may receive the first circuit board 248 (e.g., a main board). According to an embodiment, a processor (e.g., the processor 120 of FIG. 1), memory (e.g., the memory 130 of FIG. 1), and/or an interface (e.g., the interface 177 of FIG. 1) may be mounted on (directly or indirectly) the first circuit board 248. The processor may include one or more of, e.g., a central processing unit, an application processor, a graphic processing device, an image signal processing, a sensor hub processor, or a communication processor. According to various embodiments, the first circuit board 248 may include a flexible printed circuit board type radio frequency cable (FRC). The first circuit board 248 may be disposed on at least a portion of the second cover member 221 and may be electrically connected with an antenna module (e.g., the antenna module 197 of FIG. 1) and a communication module (e.g., the communication module 190 of FIG. 1).

According to an embodiment, the memory may include, e.g., a volatile or non-volatile memory.

According to an embodiment, the interface may include, e.g., a high definition multimedia interface (HDMI), a universal serial bus (USB) interface, a secure digital (SD) card interface, and/or an audio interface. The interface may electrically or physically connect, e.g., the electronic device 101 with an external electronic device and may include a USB connector, an SD card/multimedia card (MMC) connector, or an audio connector.

According to various embodiments, the electronic device 101 may include a second circuit board 249 (e.g., a sub circuit board) spaced apart from the first circuit board 248 (e.g., a main circuit board) in the first housing 201. The second circuit board 249 may be electrically connected to the first circuit board 248 through a connection flexible board. The second circuit board 249 may be electrically connected with electric components disposed in an end area of the electronic device 101, such as the battery 289 or a speaker and/or a sim socket, and may transfer signals and power. According to an embodiment, the second circuit board 249 may receive a wireless charging antenna (e.g., coil). For example, the battery 289 may receive power from an external electronic device through the wireless charging antenna. As another example, the battery 289 may transfer power to the external electronic device by the wireless charging antenna.

According to various embodiments, the battery 289 may be a device for supplying power to at least one component of the electronic device 101. The battery 189 may include a primary cell which is not rechargeable, a secondary cell which is rechargeable, or a fuel cell. The battery 289 may be integrally or detachably disposed inside the electronic device 101. According to an embodiment, the battery 289 may be formed of a single embedded battery or may include a plurality of removable batteries. According to an embodiment, the battery 289 may be positioned in a frame 213, and the battery 289 may be slid along with the frame 213.

According to various embodiments, the guide rail 250 may guide the movement of the multi-bar structure 232. For example, the multi-bar structure 232 may slide along the slit 251 formed in the guide rail 250. According to an embodiment, the guide rail 250 may be connected to the first housing 201. For example, the guide rail 250 may be connected to the first cover member 211 and/or the frame 213. According to an embodiment, the slit 251 may be referred to as a groove or recess formed in the inner surface of the guide rail 250.

According to various embodiments, the guide rail 250 may provide pressure to the multi-bar structure 232 based on the driving of the motor 241.

According to an embodiment, when the electronic device 101 changes from the closed state to opened state, the inner portion 252 of the guide rail 250 may provide pressure to the multi-bar structure 232. The multi-bar structure 232 receiving the pressure may be moved along the slit 251 of the guide rail 250, and the second housing 202 may be changed from the slide-in state to slide-out state with respect to the first housing 201. At least a portion of the display assembly 230 accommodated between the first cover member 211 and the frame 213 may be extended to the front surface.

According to an embodiment, when the electronic device 101 changes from the opened state to closed state, an outer portion 253 of the guide rail 250 may provide pressure to the bent multi-bar structure 232. The multi-bar structure 232 receiving the pressure may be moved along the slit 251 of the guide rail 250, and the second housing 202 may be changed from the slide-out state to slide-in state with respect to the first housing 201. At least a portion of the display assembly 230 may be accommodated between the first cover member 211 and the frame 213.

Referring to FIG. 5A, in the closed state of the electronic device 101, at least a portion of the second housing 202 may be disposed to be received in the first housing 201. As the second housing 202 is disposed to be received in the first housing 201, the overall volume of the electronic device 101 may be reduced. According to an embodiment, when the second housing 202 is received in the first housing 201, the size of the visually exposed display 231 may be decreased. For example, if the second housing 202 is completely received in the first housing 201, the first display area A1 of the display 231 may be visually exposed, and the second display area A2 may not be visually exposed. At least a portion of the second display area A2 may be disposed between the battery 289 and the rear plate 215 and 225.

Referring to FIG. 5B, in the opened state of the electronic device 101, at least a portion of the second housing 202 may protrude from the first housing 201. As the second housing 202 is disposed to protrude from the first housing 201, the overall volume of the electronic device 101 may be increased. According to an embodiment, if the second housing 202 protrudes from the first housing 201, at least a portion of the second display area A2 of the display 231, together with the first display area A1, may be visually exposed to the outside of the electronic device 101.

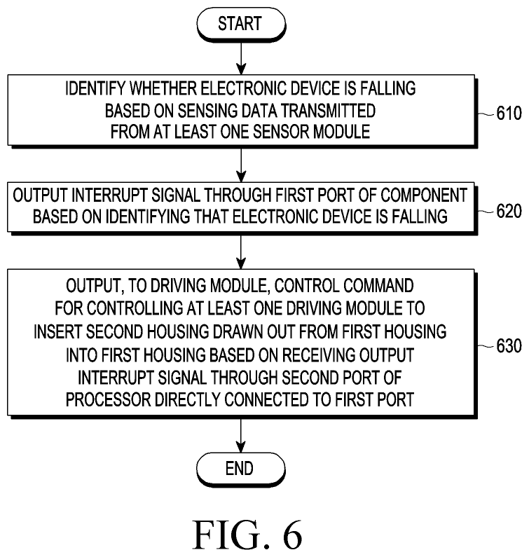

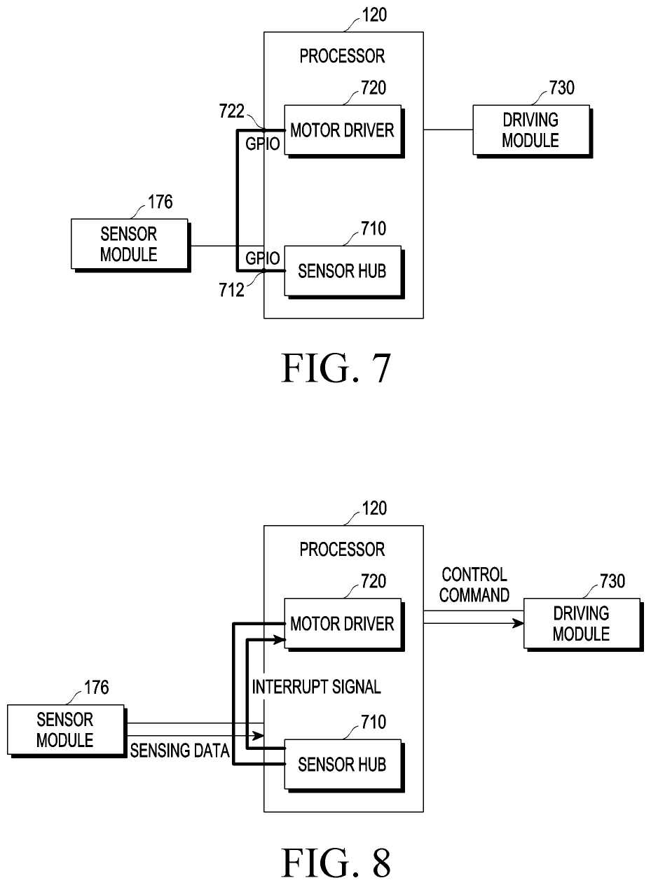

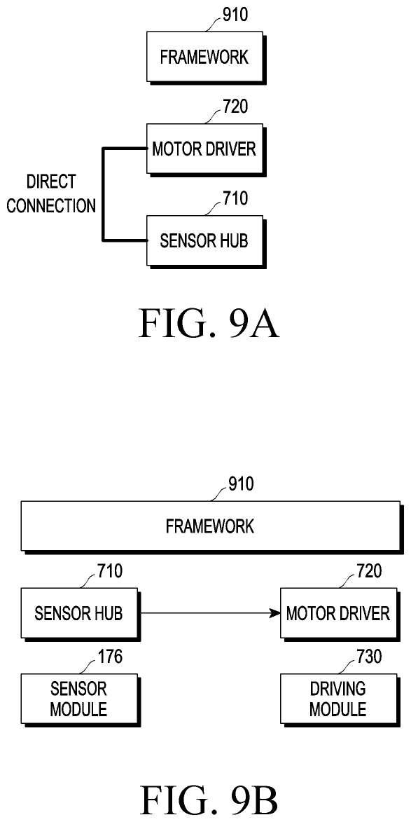

FIG. 6 is an exemplary view illustrating a function or operation for reducing latency of signal transmission by transmitting/receiving a fall interrupt signal through directly connected ports (e.g., the first port 712 and the second port 722 of FIG. 7) according to an example embodiment. FIGS. 7 and 8 are exemplary views illustrating a function or operation for transmitting/receiving a fall interrupt signal through ports (e.g., the first port 712 and the second port 722) of a processor (e.g., the processor 120 of FIG. 1) from a hardware perspective according to an example embodiment. FIGS. 9A and 9B are exemplary views illustrating a function or operation for transmitting/receiving a fall interrupt signal through ports (e.g., the first port 712 and the second port 722) of a processor from a software perspective according to an example embodiment.

In the following embodiments, each operation may be performed sequentially, but is not necessarily performed sequentially. For example, the order of the operations may be changed, and at least two operations may be performed in parallel.

According to an embodiment, it may be understood that operations 610 to 630 are performed by a processor (e.g., the processor 120 of FIG. 1) of an electronic device (e.g., the electronic device 101 of FIGS. 1 to 5B).

Referring to FIG. 6, the electronic device 101 according to an example embodiment may identify whether the electronic device 101 is falling based on sensing data transmitted from at least one sensor module (e.g., the sensor module 176 of FIG. 1). The electronic device 101 (e.g., the processor 120) according to an example embodiment may identify whether the electronic device 101 is falling based on data sensed by, e.g., a gyro sensor and/or an acceleration sensor. The electronic device 101 (e.g., the processor 120) according to an example embodiment may identify whether the user is gripping the electronic device 101 through sensing data obtained from a grip sensor included in the electronic device 101. When it is identified that the user does not grip the electronic device 101 based on sensing data obtained from the grip sensor in a state in which it is identified that the electronic device 101 is falling based on the data sensed by the gyro sensor and/or the acceleration sensor, the electronic device 101 according to an example embodiment may determine that the electronic device 101 escaped off the user and is falling. When it is identified that the user grips the electronic device 101 based on sensing data obtained from the grip sensor in a state in which it is identified that the electronic device 101 is falling based on the data sensed by the gyro sensor and/or the acceleration sensor, the electronic device 101 according to an example embodiment may determine that the electronic device 101 is falling. Operation 610 according to an example embodiment may be performed by the sensor hub 710. The sensor hub 710 according to an example embodiment may be a hardware element constituting the processor 120. The sensor hub 710 according to an example embodiment may be a hardware element that constitutes a component disposed outside the processor 120 and electrically connected to the processor 120. The sensor hub 710 according to an example embodiment is a layer positioned above the hardware stack for the sensor module 176 and may be a software element. Various functions or operations performed by the sensor hub 710 according to an example embodiment may be performed by the processor 120.

The electronic device 101 according to an example embodiment may output an interrupt signal (e.g., a fall interrupt signal) through a first port (e.g., the first port 712) of a component (e.g., the processor 120) based on identifying that the electronic device 101 is falling in operation 620. The component according to an example embodiment may include the processor 120 and/or at least one hardware element (e.g., an integrated circuit) included in the electronic device 101. Operation 620 according to an example embodiment may be performed by the sensor hub 710. When it is determined that the electronic device 101 is falling, the sensor hub 710 according to an example embodiment may output a fall interrupt signal through the first port (e.g., the first port 712) of the component (e.g., the processor 120). Alternatively, the sensor hub 710 according to an example embodiment may control a component (e.g., the processor 120) to output a fall interrupt signal through the first port (e.g., the first port 712) of the component (e.g., the processor 120) when it is determined that the electronic device 101 is falling.

In operation 630, the electronic device 101 according to an example embodiment may output a control command for controlling at least one driving module to insert the second housing (e.g., the second housing 202 of FIGS. 2 to 5B) drawn out from the first housing (e.g., the first housing 201 of FIGS. 2 to 5B) into the first housing 201 based on receiving the output interrupt signal through the second port 722 of the processor 120 directly connected to the first port 712. Operation 630 according to an example embodiment may be performed by the motor driver 720. The motor driver 720 according to an example embodiment may be a hardware element constituting the processor 120. The motor driver 720 according to an example embodiment may be a hardware element that constitutes a component disposed outside the processor 120 and electrically connected to the processor 120. The motor driver 720 according to an example embodiment is a layer constituting the kernel of the operating system and may be a software element. Various functions or operations performed by the motor driver 720 according to an example embodiment may be performed by the processor 120. The motor driver 720 according to an example embodiment may identify whether an interrupt signal is received through the second port 722 of the processor 120. When the fall interrupt signal is received, the motor driver 720 according to an example embodiment may process the received fall interrupt signal according to priority. The motor driver 720 according to an example embodiment may generate a control command for controlling the driving module 730 (e.g., the motor 241 of FIG. 4) and transmit the generated control command to the driving module 730. The control command according to an example embodiment may include at least one of information about the driving speed (e.g., maximum speed) of the driving module 730, information about the driving direction (e.g., the direction in which the second housing 202 is inserted into the first housing 201) of the driving module 730, or information about the driving time (e.g., a time taken to switch from the maximally opened state to the closed state) of the driving module 730. The motor driver 720 according to an example embodiment may identify the degree to which the second housing 202 is drawn out, and determine the time taken for the electronic device 101 to switch from the current state to the completely closed state based on the identified drawn-out degree. The motor driver 720 according to an example embodiment may determine the driving time of the driving module 730 based on the time taken, and transmit information about the determined driving time to the driving module 730. The motor driver 720 according to an example embodiment may obtain sensing data (e.g., sensing data obtained from a gyro sensor, an acceleration sensor, and/or a grip sensor) from the sensor hub 710. The motor driver 720 according to an example embodiment may again determine whether the electronic device 101 is in a state of falling (e.g., free falling) based on the obtained sensing data. The motor driver 720 according to an example embodiment may generate a control command when the state of the electronic device 101 is the falling state (e.g., free falling). When it is determined that the state of the electronic device 101 is not the falling state (e.g., free falling), the motor driver 720 according to an example embodiment may not generate a control command or may not transmit the control command to the driving module 730. The electronic device 101 (e.g., the processor 120) according to an example embodiment may determine whether the current state of the electronic device 101 is an open before performing operation 630. The electronic device 101 (e.g., the processor 120) according to an example embodiment may transmit a control command to the driving module 730 when it is determined that the current state of the electronic device 101 is the open state. When it is determined that the current state of the electronic device 101 is not the open state, the electronic device 101 (e.g., the processor 120) according to an example embodiment may not transmit a control command to the driving module 730 even if the state is not the falling state (e.g., does not generate a control command).

As shown in FIG. 9A, the sensor hub 710 and the motor driver 720 according to an example embodiment may be substantially directly connected. “Substantially directly connected state” used in the disclosure may include not only a state in which any one module and another module are connected to each other with no intervening component therebetween, but also a state in which, although a convenient intervenes between any one module and another module, the component is only configured to perform a function or operation of transferring a signal (e.g., a fall interrupt signal), but does not perform a process for changing the attributes of the signal (e.g., a fall interrupt signal). As shown in FIG. 9B, the fall interrupt signal according to an example embodiment may be transmitted substantially directly from the sensor hub 710 to the motor driver 720 without passing through the framework 910. Accordingly, the electronic device 101 capable of relatively reducing latency according to the conventional fall interrupt signal transmission/reception process may be provided.

An electronic device 101 according to an example embodiment may comprise a first housing 201, a second housing 202 disposed to be movable with respect to the first housing 201 and overlapping at least a portion of the first housing 201, at least one processor 120, a driving module 730, and at least one sensor (e.g., the sensor module 176) disposed in the second housing, and a flexible display (e.g., the display module 160 of FIG. 1) at least partially mounted on (directly or indirectly) a surface of the second housing and at least partially exposed to an outside of the electronic device. A portion of the flexible display may be inserted into or drawn out of the first housing according to driving of the driving module. The at least one processor may be configured to, based on sensing data transmitted from the at least one sensor, identify whether the electronic device is falling, based on identifying that the electronic device is falling, output an interrupt signal through a first port (e.g., the first port 712) of a component (e.g., the processor 120) of the electronic device, and output, to the at least one driving module, a control command for controlling the at least one driving module to insert the second housing drawn out from the first housing into the first housing based on receiving the output interrupt signal through a second port 722 of the processor directly connected to the first port.

The electronic device according to various example embodiments may be one of various types of electronic devices. The electronic devices may include, for example, a portable communication device (e.g., a smartphone), a computer device, a portable multimedia device, a portable medical device, a camera, a wearable device, or a home appliance. According to an example embodiment, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via at least a third element(s). Thus, for example, “connected” as used herein covers both direct and indirect connections.

As used herein, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC). Thus, each “module” herein may comprising circuitry.

Various embodiments as set forth herein may be implemented as software (e.g., the program 2540) including one or more instructions that are stored in a storage medium (e.g., internal memory 2536 or external memory 2538) that is readable by a machine (e.g., the electronic device 2501). For example, a processor of the machine (e.g., the electronic device 2501) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The storage medium readable by the machine may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various example embodiments may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to an example embodiment, each component (e.g., a module or a program) of the above-described components may include a single entity or multiple entities. Some of the plurality of entities may be separately disposed in different components. According to an example embodiment, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to an example embodiment, operations performed by the module, the program, or another component may be carried out sequentially, in parallel, repeatedly, or heuristically, or one or more of the operations may be executed in a different order or omitted, or one or more other operations may be added.

1. An electronic device, comprising:
a first housing;
a second housing configured to be movable with respect to the first housing, and overlapping at least a portion of the first housing;
wherein at least one processor comprising processing circuitry, a driving module comprising a motor, and at least one sensor are disposed at least partially in the second housing; and
a flexible display at least partially mounted on a surface of the second housing and at least partially viewable from an outside of the electronic device, wherein a portion of the flexible display is configured to be inserted into and/or drawn out of the first housing according to driving of the driving module, and wherein memory is configured to store instructions that, when executed, cause the at least one processor individually and/or collectively to:
based on sensing data transmitted from the at least one sensor, identify whether the electronic device is falling;
based on identifying that the electronic device is falling, output an interrupt signal through at least a first port of a component of the electronic device; and
based on receiving the output interrupt signal through at least a second port of the processor connected to the first port, output, to the at least one driving module, a control command for controlling the at least one driving module to insert the second housing drawn out from the first housing into the first housing.

2. The electronic device of claim 1, wherein the device is configured so that the interrupt signal is controlled to be output from the first port by a sensor hub module, comprising circuitry, configured to identify whether the electronic device is falling.

3. The electronic device of claim 2, wherein the device is configured so that the interrupt signal is to be received by a motor driver module configured to identify at least one signal received from the second port.

4. The electronic device of claim 1, wherein the instructions further include instructions to identify whether the second housing is in a state drawn out from the first housing before outputting the control command to the driving module.

5. The electronic device of claim 1, wherein at least one of the first port and the second port is a general-purpose input/output (GPIO) port of the at least one processor.

6. The electronic device of claim 1, wherein the control command includes at least one of information about a driving speed of the driving module, information about a driving direction of the driving module, or information about a driving time of the driving module.

7. The electronic device of claim 3, wherein device is configured so that the interrupt signal is to be output from the sensor hub module and directly transmitted to the motor driver without passing through a hardware abstraction layer (HAL) of an operating system and a framework of the operating system.

8. The electronic device of claim 3, wherein the sensor hub module is further configured to transmit information obtained from the at least one sensor to the motor driver, and wherein the motor driver is further configured to identify whether the electronic device is falling based on the information transmitted from the sensor hub module.

9. The electronic device of claim 1, wherein the component includes the at least one processor and/or an integrated circuit electrically connected to the at least one processor.

10. The electronic device of claim 1, wherein the instructions further include instructions to refrain the control command from being output when the second housing is completely inserted in the first housing.

11. A method, comprising:
based on sensing data transmitted from at least one sensor included in a second housing of the electronic device, identifying whether an electronic device is falling;
based on identifying that the electronic device is falling, outputting an interrupt signal through a first port of a component of the electronic device; and
based on receiving the output interrupt signal through a second port of a processor connected to the first port, outputting, to the at least one driving module, a control command for controlling at least one driving module of the electronic device to insert the second housing drawn out from a first housing of the electronic device into the first housing.

12. The method of claim 11, wherein the interrupt signal is controlled to be output from the first port by a sensor hub module configured to identify whether the electronic device is falling.

13. The method of claim 11, wherein the interrupt signal is received by a motor driver module configured to identify at least one signal received from the second port.

14. The method of claim 11, further comprising identifying whether the second housing is in a state drawn out from the first housing before outputting the control command to the driving module.

15. The method of claim 11, wherein at least one of the first port and the second port is a general-purpose input/output (GPIO) port of the processor.

16. One or more non-transitory computer-readable storage media storing instructions that, when executed by at least one processor of an electronic device individually or collectively cause the electronic device to perform operations, the operations comprising:
based on sensing data transmitted from at least one sensor included in a second housing of the electronic device, identifying whether an electronic device is falling;
based on identifying that the electronic device is falling, outputting an interrupt signal through a first port of a component of the electronic device; and
based on receiving the output interrupt signal through a second port of a processor connected to the first port, outputting, to the at least one driving module, a control command for controlling at least one driving module of the electronic device to insert the second housing drawn out from a first housing of the electronic device into the first housing.
